(19) United States
(12) Patent Application Publication
(10) Pub. No.: US 2010/0164090 A1
(43) Pub. Date: Jul. 1, 2010

(54) SEMICONDUCTOR PACKAGE APPARATUS AND MANUFACTURING METHOD THEREOF

(76) Inventor: Sang-Chul Kim, Gangnam-gu (KR)

Correspondence Address: SHERR & VAUGHN, PLLC, 620 HERNDON PARKWAY, SUITE 320, HERNDON, VA, 20170, US

(21) Appl. No.: 12/647,500

(22) Filed: Dec. 27, 2009

(30) Foreign Application Priority Data
Dec. 30, 2008 (KR) 10-2008-0137599

(51) Int. Cl. H01L 23/49; B23K 31/00; H01L 23/498

(52) U.S. Cl. 257/692; 228/180.5; 257/E23.024; 257/E23.07

(57) ABSTRACT

A semiconductor package apparatus includes a first semiconductor chip bonded onto a substrate of which metal wire turning upward; and a second semiconductor chip conductively bonded onto the first semiconductor chip in a vertical direction such that a metal wire of the second semiconductor chip and the metal wire of the first semiconductor chip have facing points. The semiconductor package apparatus includes a third semiconductor chip conductively bonded onto the first semiconductor chip in the vertical direction to be disposed horizontally with the second semiconductor chip such that a metal wire of the third semiconductor chip and the metal wire of the first semiconductor chip have facing points.

The present application claims priority under 35 U.S.C. §119 to Korean Patent Application No. 10-2008-0137599 (filed on Dec. 30, 2008), which is hereby incorporated by reference in its entirety.

### BACKGROUND

A packaging technique for a semiconductor integrated device is continuously developed with demands for miniaturization and high capacity. In recent years, various techniques for stack package satisfying miniaturization, high capacity, and packaging efficiency are developed. In the semiconductor industry, the term “stack” refers to a technique for piling up at least two semiconductor chips or packages. This technique ensures implementation of products having memory capacity larger than memory capacity which can be implemented in a process for integrating a semiconductor in a memory device and an increase in use efficiency of a packaging area.

In accordance with the manufacturing technique, a stack package is classified into a method of stacking individual semiconductor chips and then packages the stacked semiconductor chips at a time and a method of stacking individually packaged semiconductor chips. In general, the stack package is electrically connected through metal wires or a through silicon via.

A stack package using metal wires has at least two semiconductor chips stacked on a substrate through an adhesive, and the respective chips and the substrate are electrically connected to each other through the metal wire. However, in the stack package using the metal wires, electrical signals are exchanged through the metal wire, which leads to a low operation speed, requires a large number of wires, and consequently causes deterioration in the electrical characteristics of the chips. Further, to form the metal wires, an additional area is required on the substrate, which causes an increase in the package size. In addition, a gap needs to be provided for wire-bonding to the bonding pads of the respective chips, which results in an increase in the total height of the package.

To overcome these problems in the stack package using the metal wires, a stack package structure using a through electrode is proposed for preventing deterioration in the electrical characteristics of the stack package and reduction in size.

FIG. 1 is a sectional view illustrating a stack package using a through electrode.

As illustrated in FIG. 1, in the stack package using through electrodes, first semiconductor chip 10 is disposed at a bottom surface thereof and then second semiconductor chip 20 having through electrode 21 formed therein is stacked on and/or over first semiconductor chip 10. In this case, a metal wire of first semiconductor chip 10 and through electrode 21 of second semiconductor chip 20 are bonded to each other by bumps 41 and bonding agent 43. Third semiconductor chip 30 having through electrode 31 formed therein is stacked on and/or over second semiconductor chip 20. Through electrode 31 of third semiconductor chip 30 is electrically connected to through electrode 21 of second semiconductor chip 20 or the metal wire by bumps 41 or bonding agent 43. In this way, in the stack package using the through electrodes, electrical connection is made through the through electrodes. Therefore, electrical deterioration can be prevented, such that the operation speed of the semiconductor chips can be enhanced and miniaturization can be achieved.

The through electrode refers to a via of tens or hundreds rim. Accordingly, to form a through electrode of such size, it takes a lot of time and costs to the extent of several or tens times as much as a general semiconductor process. Moreover, yield is considerably low due to defects occurring when the through electrode is formed, defects when the devices are connected to each other through the bumps, and the like. Three or more devices are consumed due to one defect occurring during packaging, which causes an increase in the process costs of the products.

### SUMMARY

Embodiments relates to a semiconductor package apparatus and a method of manufacturing the same that integrates a plurality of semiconductor devices without through electrode.

Embodiments relate to a semiconductor package apparatus and a method of manufacturing the same that does not require a through electrode needs to be formed, thereby preventing the occurrence of defects caused by the through electrode.

Embodiments relate to a semiconductor package apparatus and a method of manufacturing the same that simplifies the structure of the semiconductor chip, reduces the overall process time enhances overall production yield.

In accordance with embodiments, a semiconductor package apparatus can include at least one of the following: a first semiconductor chip bonded to a substrate with a metal wire turning upward, a second semiconductor chip conductively bonded to the first semiconductor chip in a vertical direction such that a metal wire of the second semiconductor chip and the metal wire of the first semiconductor chip have facing points, and a third semiconductor chip conductively bonded to the first semiconductor chip in a vertical direction so as to be disposed horizontally with respect to the second semiconductor chip such that a metal wire of the third semiconductor chip and the metal wire of the first semiconductor chip have facing points.

In accordance with embodiments, a method of manufacturing a semiconductor package apparatus can include at least one of the following: bonding a first semiconductor chip to a substrate with a metal wire turning upward, conductively bonding a second semiconductor chip to the first semiconductor chip in a vertical direction such that a metal wire of the second semiconductor chip and the metal wire of the first semiconductor chip having facing points, and then conductively bonding a third semiconductor chip to the first semiconductor chip in the vertical direction so as to be disposed horizontally with respect to the second semiconductor chip such that a metal wire of the third semiconductor chip and the metal wire of the first semiconductor chip having facing points.

In accordance with embodiments, a semiconductor package apparatus can include at least one of the following: a first semiconductor chip having bonded to a substrate; a first wire formed in the first semiconductor chip; a second semiconductor chip conductively bonded to the first semiconductor chip; a second wire formed in the second semiconductor chip, wherein the second metal wire of the second semiconductor chip is bonded to the first metal wire of the first semiconductor chip; a third semiconductor chip conductively bonded to the first semiconductor chip; and a third wire formed in the third semiconductor chip, wherein the third metal wire of the second semiconductor chip is bonded to the first metal wire of the first semiconductor chip.

In accordance with embodiments, a semiconductor package apparatus can include at least one of the following: a substrate; a first semiconductor chip bonded to the substrate, the first semiconductor chip having a first metal wire formed therein; a second semiconductor chip conductively bonded to the first semiconductor chip, the second semiconductor chip having a second metal wire formed therein; and a third semiconductor chip conductively bonded to the first semiconductor chip such that the third semiconductor chip is disposed laterally relative to the second semiconductor chip, the third semiconductor chip having a third metal wire formed therein, the second semiconductor chip being conductively bonded to the first semiconductor chip at an interface between the first metal wiring and the second metal wiring and the third semiconductor chip being conductively bonded to the first semiconductor chip at an interface between the first metal wiring and the third metal wiring.

In accordance with embodiments, a semiconductor package apparatus can include at least one of the following: a substrate; a first semiconductor chip having a plurality of first metal wires formed therein, the first semiconductor chip being bonded to the substrate at a first surface of the first semiconductor chip such that a second surface of the first semiconductor chip is exposed; a second semiconductor chip having a plurality of second metal wires formed therein that are spatially aligned and corresponds to a first set of the first metal wires, the second semiconductor chip being conductively bonded to the first semiconductor chip at the exposed second surface of the first semiconductor chip and at an interface between the second metal wires and the first metal wires; and a third semiconductor chip having a plurality of third metal wires formed therein that are spatially aligned and corresponds to a second set of the first metal wires, the third semiconductor chip being conductively bonded to the first semiconductor chip at the exposed second surface of the first semiconductor chip on the same plane as the second semiconductor chip and at an interface between the third metal wires and the first metal wires.

### DRAWINGS

FIG. 1 illustrates a stack package using through electrodes.

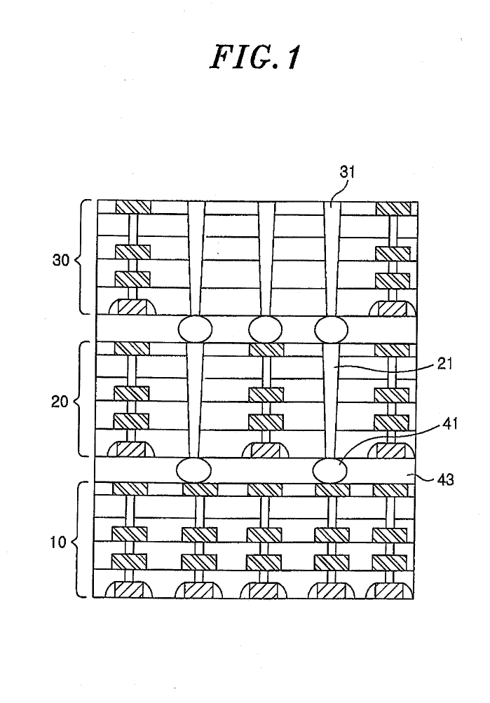

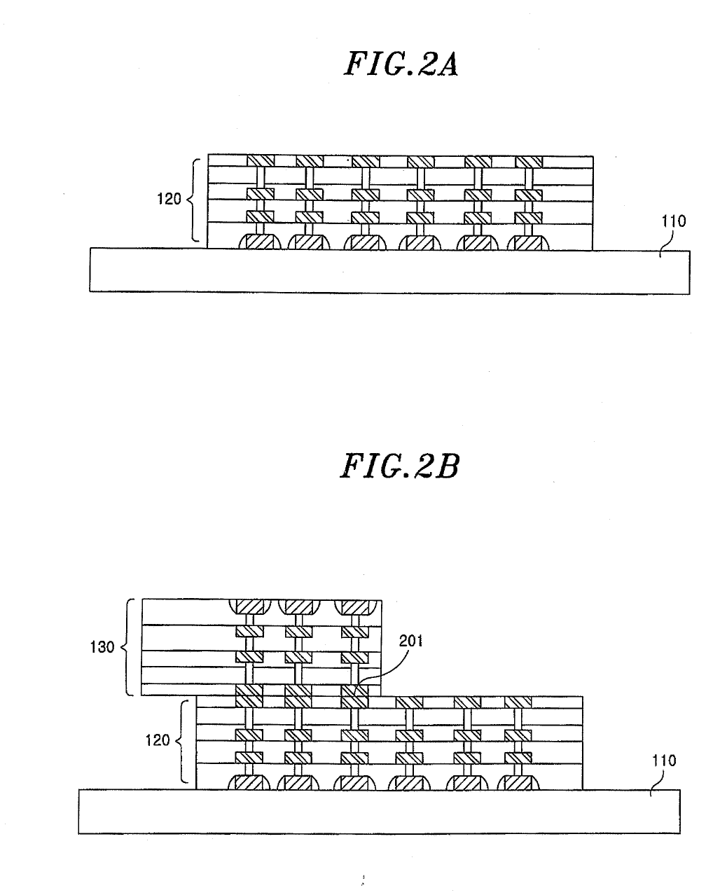

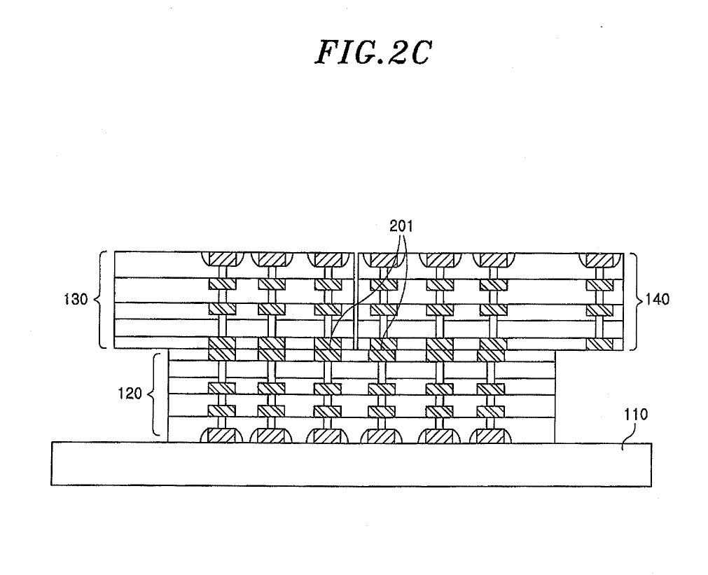

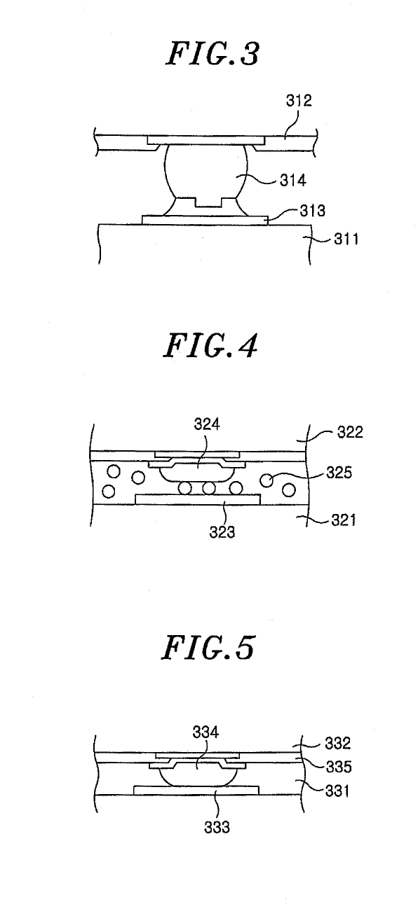

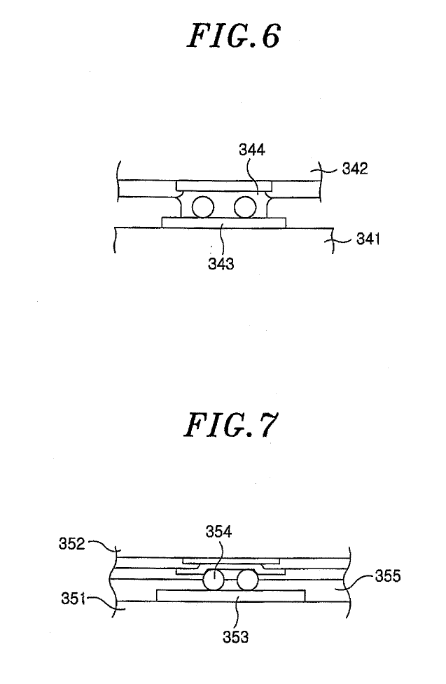

Example FIGS. 2A to 7 illustrate a method of manufacturing a semiconductor package and a bonding structure of semiconductor chips, in accordance with embodiments.

### DESCRIPTION

Hereinafter, embodiments will be described in detail with reference to the accompanying drawings which form a part hereof.

Example FIGS. 2A to 2C are views illustrating a method of manufacturing a semiconductor package apparatus in accordance with embodiments.

First, the structure of a semiconductor package apparatus in accordance with embodiments will be described with reference to example FIG. 2C.

As illustrated in example FIG. 2C, the semiconductor package apparatus includes first semiconductor chip 120 having at least a first metal wire formed therein. First semiconductor chip 120 is bonded to substrate 110 at a first surface thereof such that a second surface thereof is exposed.

Second semiconductor chip 130 has at least a second metal wire formed therein. Second semiconductor chip 130 is conductively bonded to first semiconductor chip 120 at the exposed second surface of first semiconductor chip 120. Particularly, second semiconductor chip 130 is conductively bonded to first semiconductor chip 120 at interface 201 between the second metal wire of second semiconductor chip 130 and the first metal wire of first semiconductor chip 120.

Third semiconductor chip 140 has at least a third metal wire formed therein. Third semiconductor chip 140 is conductively bonded to first semiconductor chip 120 at the exposed second surface of first semiconductor chip 120. Particularly, third semiconductor chip 130 is conductively bonded to first semiconductor chip 120 at interface 201 between the third metal wire of third semiconductor chip 140 and the first metal wire of first semiconductor chip 120. Accordingly, second semiconductor chip 130 and third semiconductor chip 140 are conductively bonded to first semiconductor chip 120 such that they are disposed laterally adjacent to each other.

Details of a process for manufacturing a semiconductor package apparatus configured as above will be described.

As illustrated in example FIG. 2A, first semiconductor chip 120 is bonded to substrate 110 in a vertical direction. First semiconductor chip 120 is bonded to substrate 110 at a first surface of first semiconductor chip 120 such that a second surface of first semiconductor chip 120 is exposed. Particularly, first semiconductor chip 120 is disposed such that the first metal wire formed therein is exposed. Substrate 110 and first semiconductor chip 120 may be bonded to each other using, e.g., resin or epoxy.

As illustrated in example FIG. 2B, second semiconductor chip 130 is conductively bonded to first semiconductor chip 120 in a vertical direction. Second semiconductor chip 130 is conductively bonded to first semiconductor chip 120 at the exposed second surface of first semiconductor chip 120. Second semiconductor chip 130 is disposed such that the second metal wire formed therein corresponds spatially to the first metal wire of first semiconductor chip 120. Second semiconductor chip 130 is conductively bonded to first semiconductor chip 120 at interface 201 between the second metal wire of second semiconductor chip 130 and the first metal wire of first semiconductor chip 120. The bonding method between first semiconductor chip 120 and second semiconductor chip 130 may be implemented in various ways, and will be described below with reference to example FIGS. 3 to 7.

As illustrated in example FIG. 2C, third semiconductor chip 140 is conductively bonded to first semiconductor chip 120 in a vertical direction such that it is disposed laterally with respect to second semiconductor chip 130 and vertically with respect to first semiconductor chip 120. Third semiconductor chip 140 is conductively bonded to first semiconductor chip 120 at the exposed second surface of first semiconductor chip 120. Third semiconductor chip 140 is disposed such that the third metal wire formed therein corresponds spatially to the first metal wire of first semiconductor chip 120. Third semiconductor chip 140 is conductively bonded to first semiconductor chip 120 at interface 201 between the third metal wire of third semiconductor chip 140 and the first metal wire of first semiconductor chip 120. The bonding method between first semiconductor chip 120 and third semiconductor chip 140 may be implemented in various ways, and will be described below with reference to example FIGS. 3 to 7.

As described above, with the method of manufacturing a semiconductor package apparatus in accordance with embodiments, first semiconductor chip 120 is first bonded to substrate 110. Accordingly, even if second semiconductor chip 130 and third semiconductor chip 140 are different in thickness, a semiconductor package apparatus can be manufactured by vertical and horizontal adhesion.

In accordance with embodiments, since second semiconductor chip 130 and third semiconductor chip 140, i.e., other than first semiconductor chip 120 as a reference, are present in a form of flip chips, second semiconductor chip 130 and third semiconductor chip 140 can be electrically connected directly to first semiconductor chip 120 at the same exposed surface of first semiconductor chip 120. Therefore, no formation of one or more through electrodes is required.

Therefore, in accordance with embodiments, since no through electrode needs to be formed, defects that may occur when a through electrode is formed can be prevented, the structure of the semiconductor chip can be simplified, and a process time can be reduced, which ensures enhanced in yield.

Example FIGS. 3 to 7 are sectional views illustrating the bonding structure of semiconductor chips in accordance with embodiments.

Example FIG. 3 is a sectional view illustrating the bonding structure of semiconductor chips in accordance with embodiments.

As illustrated in example FIG. 3, first semiconductor chip 311, second semiconductor chip 312, third semiconductor chip 312, conductive film 313 and a metal ball 314 are provided. The metal wires of two of the semiconductor chips can be conductively bonded to each other using conductive film 313 and metal ball 314. Metal ball 314 may be composed of Au.

Example FIG. 4 is a sectional view of the bonding structure of semiconductor chips in accordance with embodiments.

As illustrated in example FIG. 4, first semiconductor chip 321, second semiconductor chip 322, third semiconductor chip 322, conductive film 323, metal bumps 324 and anisotropic conductive film (ACF) 325 are provided. The metal wires of two of the semiconductor chips using conductive film 323, metal bumps 324 and ACF 325 are conductively bonded together. Metal bumps 324 can be composed of Au bump.

Example FIG. 5 is a sectional view illustrating a bonding structure of semiconductor chips in accordance with embodiments.

As illustrated in example FIG. 4, first semiconductor chip 331, second semiconductor chip 332 or third semiconductor chip 332, conductive film 333, metal bump 334, and photopolymerizable resin 335 are provided. The metal wires of two of the semiconductor chips can be conductively bonded to each other using conductive film 333, metal bump 334, and photopolymerizable resin 335. Metal bump 334 can be composed of Au and photopolymerizable resin 335 can be composed of an ultraviolet (UV) curable resin.

Example FIG. 6 is a sectional view illustrating a bonding structure of semiconductor chips in accordance with embodiments.

As illustrated in example FIG. 6, first semiconductor chip 341, second semiconductor chip 342 or third semiconductor chip 342, conductive film 343, and conductive particles 344 are provided. The metal wires of two of the semiconductor chips can be conductively bonded to each other using conductive film 343 and conductive particle 344.

Example FIG. 7 is a sectional view illustrating a bonding structure of semiconductor chips in accordance with embodiments.

As illustrated in example FIG. 7, first semiconductor chip 351, second semiconductor chip 352 or third semiconductor chip 352, conductive film 353, conductive particles 354 and photopolymerizable resin 355 are provided. The metal wires of two of the semiconductor chips can be conductively bonded to each other using conductive film 353, conductive particles 354, and photopolymerizable resin 355. Photopolymerizable resin 355 can be composed of a UV curable resin.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a substrate;
a first semiconductor chip bonded to the substrate, the first semiconductor chip having a first metal wire formed therein;
a second semiconductor chip conductively bonded to the first semiconductor chip, the second semiconductor chip having a second metal wire formed therein; and
a third semiconductor chip conductively bonded to the first semiconductor chip such that the third semiconductor chip is disposed laterally relative to the second semiconductor chip, the third semiconductor chip having a third metal wire formed therein,
wherein the second semiconductor chip is conductively bonded to the first semiconductor chip at an interface between the first metal wiring and the second metal wiring and the third semiconductor chip is conductively bonded to the first semiconductor chip at an interface between the first metal wiring and the third metal wiring.

2. The apparatus of claim 1, wherein the second semiconductor chip and the third semiconductor chip are conductively bonded to the first semiconductor chip, respectively, using a conductive film and a metal ball.

3. The apparatus of claim 1, wherein the second semiconductor chip and the third semiconductor chip are conductively bonded to the first semiconductor chip, respectively, using a conductive film, metal bumps, and an anisotropic conductive film.

4. The apparatus of claim 1, wherein the second semiconductor chip and the third semiconductor chip are conductively bonded to the first semiconductor chip, respectively, using a conductive film, a metal bump and photopolymerizable resin.

6. The apparatus of claim 1, wherein the second semiconductor chip and the third semiconductor chip are conductively bonded to the first semiconductor chip, respectively, using a conductive film and conductive particles.

7. The apparatus of claim 1, wherein the second semiconductor chip and the third semiconductor chip are conductively bonded to the first semiconductor chip, respectively, using a conductive film, conductive particles and photopolymerizable resin.

8. The apparatus of claim 1, wherein the apparatus comprises a semiconductor package.

9. A method comprising:
bonding a first semiconductor chip having a first metal wire to a substrate;
conductively bonding a second semiconductor chip having a second metal wire to the first semiconductor chip at an interface between the second metal wire and the first metal wire; and
conductively bonding a third semiconductor chip having a third metal wire to the first semiconductor chip at an interface between the third metal wire and the first metal wire such that the third semiconductor chip is disposed laterally relative to the second semiconductor chip.

10. The method of claim 9, wherein the second semiconductor chip and the third semiconductor chip are conductively bonded to the first semiconductor chip, respectively, using a conductive film and a metal ball.

11. The method of claim 9, wherein the second semiconductor chip and the third semiconductor chip are conductively bonded to the first semiconductor chip, respectively, using a conductive film, metal bumps and an anisotropic conductive film.

12. The method of claim 9, wherein the second semiconductor chip and the third semiconductor chip are conductively bonded to the first semiconductor chip, respectively, using a conductive film, metal bumps and photopolymerizable resin.

13. The method of claim 9, wherein the second semiconductor chip and the third semiconductor chip are conductively bonded to the first semiconductor chip, respectively, using a conductive film and conductive particles.

14. The method of claim 9, wherein the second semiconductor chip and the third semiconductor chip are conductively bonded to the first semiconductor chip, respectively, using a conductive film, conductive particles and photopolymerizable resin.

15. An apparatus comprising:
a substrate;
a first semiconductor chip having a plurality of first metal wires formed therein, the first semiconductor chip being bonded to the substrate at a first surface of the first semiconductor chip such that a second surface of the first semiconductor chip is exposed;
a second semiconductor chip having a plurality of second metal wires formed therein that are spatially aligned and corresponds to a first set of the first metal wires, the second semiconductor chip being conductively bonded to the first semiconductor chip at the exposed second surface of the first semiconductor chip and at an interface between the second metal wires and the first metal wires; and
a third semiconductor chip having a plurality of third metal wires formed therein that are spatially aligned and corresponds to a second set of the first metal wires, the third semiconductor chip being conductively bonded to the first semiconductor chip at the exposed second surface of the first semiconductor chip on the same plane as the second semiconductor chip and at an interface between the third metal wires and the first metal wires.

16. The apparatus of claim 15, wherein the second semiconductor chip and the third semiconductor chip are conductively bonded to the first semiconductor chip, respectively, using a conductive film and a metal ball.

17. The apparatus of claim 15, wherein the second semiconductor chip and the third semiconductor chip are conductively bonded to the first semiconductor chip, respectively, using a conductive film, metal bumps, and an anisotropic conductive film.

18. The apparatus of claim 15, wherein the second semiconductor chip and the third semiconductor chip are conductively bonded to the first semiconductor chip, respectively, using a conductive film, a metal bump and photopolymerizable resin.

19. The apparatus of claim 15, wherein the second semiconductor chip and the third semiconductor chip are conductively bonded to the first semiconductor chip, respectively, using a conductive film and conductive particles.

20. The apparatus of claim 15, wherein the second semiconductor chip and the third semiconductor chip are conductively bonded to the first semiconductor chip, respectively, using a conductive film, conductive particles and photopolymerizable resin.
